(19) United States
(12) Patent Application Publication
(10) Pub. No.: US 2025/0275070 A1
(43) Pub. Date: Aug. 28, 2025

(54) FLEXIBLE DISPLAY DEVICE

(71) Applicant: LG Display Co., Ltd., Seoul (KR)

(72) Inventors: Daeyun Kim, Seoul (KR); MiJin Han, Seoul (KR); Hosung Park, Paju-si (KR)

(73) Assignee: LG Display Co., Ltd., Seoul (KR)

(21) Appl. No.: 18/894,985

(22) Filed: Sep. 24, 2024

(30) Foreign Application Priority Data
Feb. 28, 2024 (KR) 10-2024-0028665

(51) Int. Cl. H05K 5/02

(52) U.S. Cl. CPC H05K 5/0217

(57) ABSTRACT

A flexible display device may include a flexible display panel, and a back cover at a rear surface of the flexible display panel and supporting the flexible display panel. The back cover may include a plurality of first members extending in a first direction, and a plurality of second members extending in a second direction and intersecting the plurality of first members. The plurality of second members may include a different material from the plurality of first members.

### CROSS-REFERENCE TO RELATED APPLICATION

This application claims the priority of Korean Patent Application No. 10-2024-0028665 filed on Feb. 28, 2024, in the Korean Intellectual Property Office, the disclosure of which is incorporated herein by reference.

### BACKGROUND

### Field

The present disclosure relates to a display device and, more particularly, to a flexible display device whose manufacturing cost is reduced and whose flexibility is improved.

### Description of the Related Art

Display devices used for such applications as a computer monitor, a television, or a cellular phone include an organic light emitting display (OLED) device, which is a self-emitting device, and a liquid crystal display (LCD) device, which requires a separate light source.

A range of applications for display devices is diversified to, among other things, personal digital assistants, computer monitors, and televisions, and display devices with a large display area and a reduced volume and weight are being studied.

Further, recently, a flexible display device manufactured by forming display elements and lines on a flexible substrate, made of a flexible material like plastic, so as to be capable of displaying images even in a folded or rolled state is receiving attention as a next generation display device.

### SUMMARY

An object of the present disclosure is to provide a flexible display device with a reduced manufacturing cost.

Another object of the present disclosure is to provide a flexible display device with a reduced defect rate.

Yet another object of the present disclosure is to provide a flexible display device having a simplified structure.

Objects of the present disclosure are not limited to the above-mentioned objects, and other objects, which are not mentioned above, can be clearly understood by those skilled in the art from the following descriptions.

To achieve these objects and other advantages of the present disclosure, as embodied and broadly described herein, a flexible display device may include: a flexible display panel; and a back cover at a rear surface of the flexible display panel and supporting the flexible display panel. The back cover may include: a plurality of first members extending in a first direction; and a plurality of second members extending in a second direction and intersecting the plurality of first members, the plurality of second members including a different material from the plurality of first members.

In another aspect of the present disclosure, a display device, having a malleable area and at least one rigid area adjacent to the malleable area, may include: a flexible display panel in the malleable area; and a back cover at a rear surface of the flexible display panel and supporting the flexible display panel. The back cover may include: a plurality of first members in the malleable area and extending in a first direction; and a plurality of second members in the malleable area and intersecting the plurality of first members in a mesh pattern, the plurality of second members including a different material from the plurality of first members.

Other detailed matters of example embodiments are included in the detailed description and the drawings.

According to the present disclosure, anisotropic properties of a flexible display device can be maintained by using a high rigidity material and a low rigidity material.

According to the present disclosure, a manufacturing process of the flexible display device can be simplified by using a back cover having a mesh structure.

According to the present disclosure, a manufacturing cost of the flexible display device can be reduced by simplifying the manufacturing process.

The advantages and effects according to the present disclosure are not limited to those described above, and additional advantages and effects are included in or may be obtained from the present specification.

Additional features and aspects of the disclosure will be set forth in the description that follows and in part will become apparent from the description or may be learned by practice of the inventive concepts provided herein. Other features and aspects of the inventive concepts may be realized and attained by the structure particularly pointed out in, or derivable from, the written description, claims hereof, and the appended drawings.

It is to be understood that both the foregoing general description and the following detailed description of the present disclosure are by way of example and are intended to provide further explanation of the disclosures as claimed.

### BRIEF DESCRIPTION OF DRAWINGS

The accompanying drawings, which are included to provide a further understanding of the disclosure and are incorporated in and constitute a part of this application, illustrate example embodiments of the disclosure and together with the description serve to explain the principles of the disclosure. In the drawings:

FIG. 1 and FIG. 2 are perspective views of flexible display devices according to an example embodiment of the present disclosure;

FIG. 3 is a schematic exploded perspective view of a flexible display device according to an example embodiment of the present disclosure;

FIG. 4A and FIG. 4B are schematic cross-sectional views of the flexible display device according to an example embodiment of the present disclosure taken along line A-A′ and line B-B′, respectively, in FIG. 3;

FIG. 5 is a plan view of a back cover of the flexible display device according to an example embodiment of the present disclosure;

FIG. 6 is a perspective view of area A of FIG. 5;

FIG. 7 is a schematic cross-sectional view of a flexible display device according to another example embodiment of the present disclosure;

FIG. 8 is a schematic plan view of a flexible display device according to yet another example embodiment of the present disclosure;

FIG. 9A and FIG. 9B are schematic cross-sectional views of the flexible display device according to yet another example embodiment of the present disclosure taken along line C-C′ and line D-D′, respectively, in FIG. 8; and

FIG. 10 is a schematic cross-sectional view of a flexible display device according to still another example embodiment of the present disclosure.

### DETAILED DESCRIPTION

Advantages and features of the present disclosure and methods of achieving them will become apparent with reference to the example embodiments described below in detail in conjunction with the accompanying drawings. The present disclosure may, however, be embodied in different forms and should not be construed as limited to the example embodiments set forth herein. Rather, these example embodiments are provided so that this disclosure will be thorough and complete and will fully convey the scope of the present disclosure to those skilled in the art.

The shapes, dimensions, areas, lengths, thicknesses, ratios, angles, numbers, and the like, which are illustrated in the drawings to describe various example embodiments of the present disclosure, are merely given by way of example. Therefore, the present disclosure is not limited to such illustrated details in the drawings. Like reference numerals generally denote like elements throughout the specification, unless otherwise specified.

In the following description, where a detailed description of a relevant known function or configuration may unnecessarily obscure aspects of the present disclosure, a detailed description of such a known function or configuration may be omitted or be briefly discussed.

Where a term like “comprise,” “have,” “include,” “contain,” “constitute,” “made up of,” or “formed of” is used, one or more other elements may be added unless the term is used with a more limiting term, such as “only” or the like. An element described in a singular form may include a plurality of elements, and vice versa, unless the context clearly indicates otherwise.

In construing an element, the element should be construed as including an error or tolerance range even where no explicit description of such an error or tolerance range is provided.

Where a positional relationship between two elements is described with such a term as “on,” “above,” “below,” “beneath,” “next,” or the like, one or more other elements may be located between the two elements unless the term is used with a more limiting term, such as “direct(ly).”

For example, where a first element is described as being positioned “on” a second element, the first element may be positioned above and contact the second element or may merely be above the second element with one or more additional elements disposed between the first and second elements.

Although terms “first,” “second,” and the like may be used herein to describe various elements, these elements should not be interpreted to be limited by these terms as they are not used to define a particular essence, order, sequence, precedence, or number of such elements. These terms are used only to refer one element separately from another. For example, a first element could be termed a second element, and a second element could similarly be termed a first element, without departing from the scope of the present disclosure.

A size and a thickness of each component illustrated in the drawings are illustrated for convenience of description, and the present disclosure is not limited to the specific size or thickness of the component illustrated.

Features of various embodiments of the present disclosure may be partially or wholly coupled to or combined with each other, and may be operated, linked, or driven together in various ways as those skilled in the art can sufficiently understand. The embodiments of the present disclosure may be carried out independently from each other, or may be carried out together in association with each other.

Hereinafter, various example embodiments of the present disclosure will be described in detail with reference to the accompanying drawings.

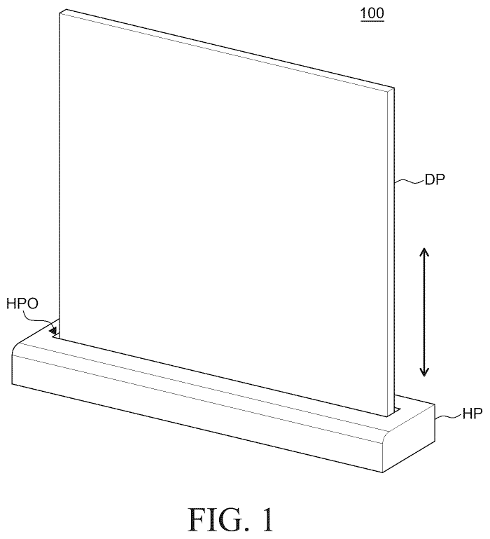

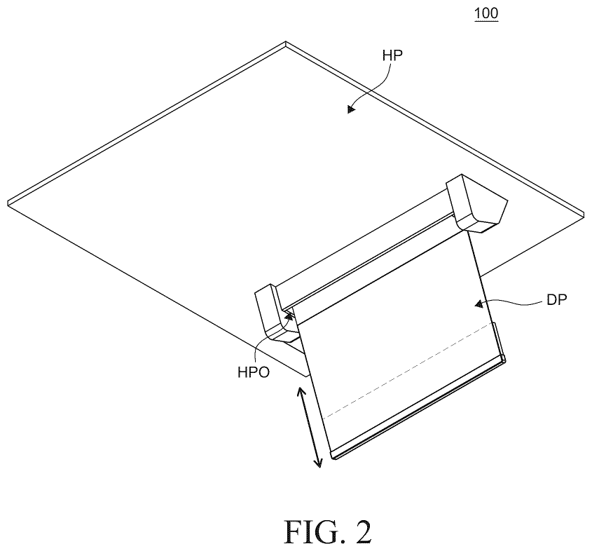

FIG. 1 and FIG. 2 are perspective views of flexible display devices according to an example embodiment of the present disclosure. Specifically, FIG. 1 is a perspective view of an example rollable display device. FIG. 2 is a perspective view of an example slidable display device. As illustrated in FIG. 1 and FIG. 2, a flexible display device 100 according to an example embodiment of the present disclosure may include a display part DP and a housing part HP.

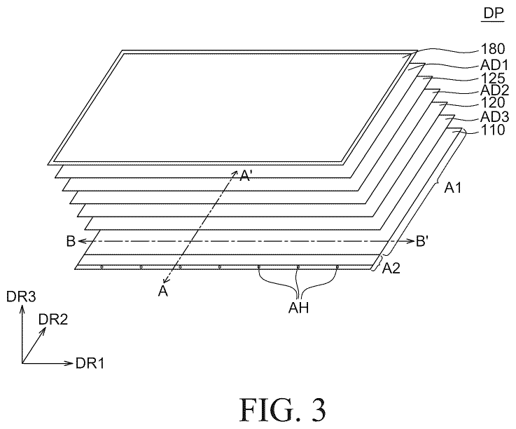

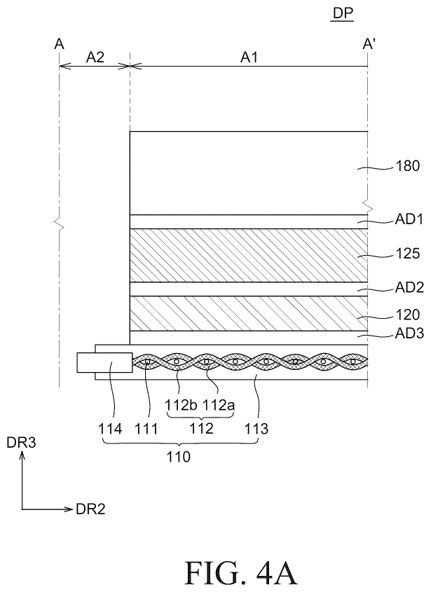

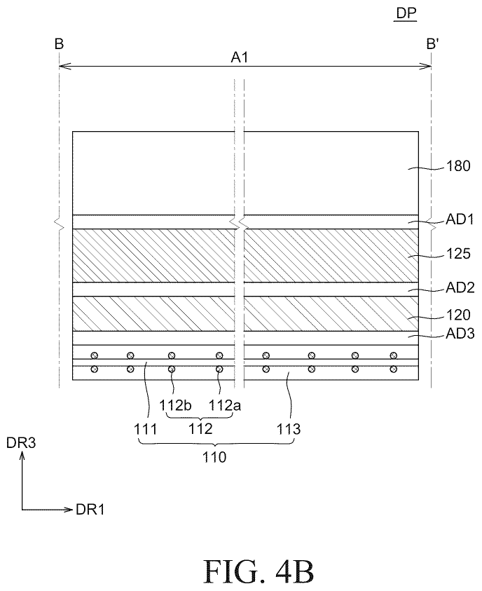

The display part DP is configured to display images to a user. For example, the display part DP may include display elements, as well as circuits, lines, and components for driving the display element. In this case, the flexible display device 100 according to an example embodiment of the present disclosure may include a display panel 120 and a back cover 110 each having flexibility. The display part DP will be described below in more detail with reference to FIG. 3 through FIG. 4B.

The housing part HP is a case in which the display part DP may be accommodated.

The housing part HP may have an opening HPO to allow the display part DP to be wound into the housing part HP and to be unwound out of the housing part HP.

As shown in FIG. 1, if the flexible display device is a rollable display device, the display part DP may be configured to be rollable. For example, by movement of a roller (not shown), the display part DP of the flexible display device 100 may be switched from a fully unwound state to a fully wound state or from a fully wound state to a fully unwound state. For example, when the roller (not shown) is rotated in a counter-clockwise direction, the display part DP wound around the roller (not shown) may be unwound from the roller (not shown) to be disposed outside the housing part HP. Also, when the roller (not shown) is rotated in a clockwise direction, the display part DP disposed outside the housing part HP may be wound around the roller (not shown) and accommodated in the housing part HP.

As shown in FIG. 2, if the flexible display device is a slidable display device, the display part DP may be configured to be slidable and bendable. For example, the display part DP of the flexible display device 100 may be disposed outside of the housing part HP by movement of a guide member (not shown). For example, the display part DP may slide between a plurality of rollers (not shown) disposed to face each other. Specifically, by movement of the plurality of rollers (not shown), the display part DP may slide out of the housing part HP or may slide in to be accommodated in the housing part HP. Herein, the display part DP may slide out of the housing part HP at a certain inclination. For example, the display part DP accommodated flat in the housing part HP may extend to the outside of the housing part HP and may be bent at an angle, for example, in a range of 900 to 130°. Therefore, a portion of the display part DP disposed in the housing part HP may be inclined with respect to another portion of the display part DP disposed outside the housing part HP.

FIG. 3 is a schematic exploded perspective view of a flexible display device according to an example embodiment of the present disclosure. FIG. 4A and FIG. 4B are schematic cross-sectional views of the flexible display device according to an example embodiment of the present disclosure. FIG. 4A is a cross-sectional view taken along the line A-A′ of FIG. 3. FIG. 4B is a cross-sectional view taken along the line B-B′ of FIG. 3.

As illustrated in FIG. 3 through FIG. 4B, the display part DP may include a malleable area A1 and a rigid area A2.

The malleable area A1 is an area where the display panel 120 may be bent, slid, or rolled.

The malleable area A1 may overlap at least the display panel 120 among the components of the display part DP. For example, the entire display panel 120 may overlap the malleable area A1 or be disposed in the malleable area A1.

The rigid area A2 is configured to support some components of the display part DP.

The rigid area A2 may be disposed adjacent to the malleable area A1 and disposed outside the malleable area A1. For example, the rigid area A2 and the malleable area A1 may be disposed along a bending, sliding, or rolling direction of the display part DP. For example, the display part DP may be bent, slid, or rolled in a second direction DR2. Thus, the rigid area A2 and the malleable area A1 may be disposed adjacent to each other along the second direction DR2.

The rigid area A2 may be disposed outside the display panel 120. For example, in the rigid area A2, the back cover 110 may be fastened to a driver configured to move the display part DP to the outside of the housing part HP or accommodate the display part DP in the housing part HP.

For example, the flexible display device 100 may be a rollable display device. In this case, a plate 114 may be fastened to the roller (not shown), which the display part DP may be wound around or unwound from, in the rigid area A2 disposed at a lowermost region of the back cover 110.

If the flexible display device 100 is a slidable display device, the plate 114 may be fastened to a driver which reciprocates to slide the flexible display device 100.

Although not shown in FIG. 3, the rigid area A2 may also be disposed at an uppermost region of the back cover 110. The back cover 110 may be fixed to a head bar in the rigid area A2 disposed at the uppermost region. Since the display part DP may be fixed to the head bar of the driver, the display part DP can be wound or slid into the housing part HP and unwound or slid out of the housing part HP depending on an operation of the driver.

FIG. 3 illustrates the rigid area A2 disposed at only one side of the malleable area A1, but the present disclosure is not limited thereto. The rigid area A2 may be disposed at both sides of the malleable area A1. For example, the display part DP of the flexible display device 100 may be slid or rolled depending on the rise or fall of a link part (not shown). In this case, a fastening region where the link part (not shown) is fastened may be disposed at an upper portion of the malleable area A1. For example, the fastening region may be disposed in the rigid area A2 at an upper portion of the display part DP. Thus, the rigid area A2 disposed at the upper portion of the display part DP may serve to support the link part (not shown).

The display part DP may include the back cover 110, the display panel 120, a polarizing plate 125, a cover window 180, a first adhesive layer AD1, a second adhesive layer AD2, and a third adhesive layer AD3. For example, the back cover 110 may be disposed in the malleable area A1 and in the rigid area A2. Also, the back cover 110, the display panel 120, the polarizing plate 125, the cover window 180, the first adhesive layer AD1, the second adhesive layer AD2, and the third adhesive layer AD3 may be disposed in the malleable area A1.

As illustrated in FIG. 3, the cover window 180 may be disposed in the malleable area A1. The cover window 180 may correspond in shape to the display panel 120 and may be disposed to cover the display panel 120. The cover window 180 may serve to protect the display panel 120 from external impacts, moisture, heat, and the like.

In the malleable area A1, the first adhesive layer AD1 may be disposed between the cover window 180 and the polarizing plate 125. The first adhesive layer AD1 may fix the polarizing plate 125 and the cover window 180 together. The first adhesive layer AD1 may be made of an optical clear adhesive (OCA) but is not limited thereto. The OCA may serve to minimize particles or bubbles between the polarizing plate 125 and the cover window 180.

In the malleable area A1, the polarizing plate 125 may be disposed on a rear surface of the first adhesive layer AD1. The polarizing plate 125 may selectively transmit light to reduce the reflection of external light incident onto the display panel 120. Specifically, the display panel 120 may contain various metal materials applied to semiconductor elements, lines, organic light emitting elements, and the like. Therefore, the external light incident onto the display panel 120 may be reflected from the metal materials so that the visibility of the flexible display device 100 may be reduced due to the reflection of the external light. Therefore, the polarizing plate 125 may serve to suppress the reflection of the external light and increase the outdoor visibility of the flexible display device 100. However, the polarizing plate 125 may be omitted in some embodiments depending on implementation of the flexible display device 100.

In the malleable area A1, the second adhesive layer AD2 may be disposed between the polarizing plate 125 and the display panel 120. The second adhesive layer AD2 may fix the polarizing plate 125 and the display panel 120 together. The second adhesive layer AD2 may be made of an optical clear adhesive (OCA) but is not limited thereto. The OCA may serve to minimize particles or bubbles between the polarizing plate 125 and the display panel 120.

The display panel 120 may be disposed on a rear surface of the polarizing plate 125. The display panel 120 may be disposed in the malleable area A1 on one surface of the back cover 110.

The display panel 120 is configured to display images to the user. In the display panel 120, display elements for displaying images, driving elements for driving the display elements, and lines for transmitting various signals to the display elements and the driving elements may be disposed.

Different types of display elements may be employed depending on the type of the display panel 120. For example, if the display panel 120 is an organic light emitting display panel, the display elements may include organic light emitting elements each composed of an anode, an organic emission layer, and a cathode. For example, if the display panel 120 is a liquid crystal display panel, the display elements may include liquid crystal display elements. Hereinafter, the display panel 120 will be described as an organic light emitting display panel, but the display panel 120 is not limited to the organic light emitting display panel. Also, the display panel 120 of the flexible display device 100 according to an example embodiment of the present disclosure may be implemented as a flexible display panel to be bent, slid, or rolled.

The display panel 120 may include a display area and a non-display area.

The display area is an area where images are to be displayed on the display panel 120. A plurality of sub-pixels constituting each of a plurality of pixels and driver circuits for driving the plurality of sub-pixels may be disposed in the display area. The plurality of sub-pixels may be minimum units of the display area. A display element may be disposed in each of the plurality of sub-pixels. For example, an organic light emitting element including an anode, an organic emission layer, and a cathode may be disposed in each of the plurality of sub-pixels. However, the present disclosure is not limited thereto. Also, the driver circuits for driving the plurality of sub-pixels may include driving elements, lines, and the like. For example, the driver circuits may be composed of thin film transistors, storage capacitors, gate lines, data lines, and the like, but are not limited thereto.

The non-display area may be an area where no image is displayed. Various lines, circuits, and the like for driving the organic light emitting elements in the display area may be disposed in the non-display area. For example, link lines for transmitting signals to the sub-pixels and to the driver circuits in the display area or driver ICs, such as a gate driver IC and a data driver IC, may be disposed in the non-display area. However, the present disclosure is not limited thereto.

The non-display area may include a pad area. The pad area is an area where a plurality of pads is disposed. The plurality of pads may serve as electrodes to electrically connect a plurality of flexible films to the display panel 120. The plurality of flexible films and the display panel 120 can be electrically connected to each other through the plurality of pads. The pad area may be disposed overlapping the rigid area A2. However, the disposition of the pad area is not limited thereto.

As illustrated in FIG. 3, in the malleable area A1, the third adhesive layer AD3 may be disposed between the display panel 120 and the back cover 110. The third adhesive layer AD3 may bond the display panel 120 to the back cover 110 together. The third adhesive layer AD3 may be made of a pressure sensitive adhesive (PSA) but is not limited thereto. The PSA may serve to minimize particles or bubbles between the display panel 120 and the back cover 110.

As shown in FIG. 3 through FIG. 4B, the back cover 110 may be disposed on a rear surface of the display panel 120.

The back cover 110 may have a greater size than the display panel 120. For example, the back cover 110 may be located in the malleable area A1, where the display panel 120 is disposed, and may also be located in the rigid area A2 disposed outside the malleable area A1.

Also, the back cover 110 may serve to support the display panel 120 and protect the display part DP from the outside. The back cover 110 is disposed on the rear surface of the display panel 120 so that it may be referred to as a back cover, but the position of the back cover 110 is not limited thereto.

Also, the back cover 110 can be bent, slid, or rolled together with the display panel 120 in the malleable area A1. For example, the back cover 110 may be bent, slid, or rolled in the second direction DR2, and the display panel 120 may be bent, slid, or rolled together with the back cover 110.

The back cover 110 may contain a malleable material to suppress deformation even when the display panel 120 is repeatedly bent, slid, or rolled.

As illustrated in FIG. 4A and FIG. 4B, the back cover 110 may include a plurality of first members 111, a plurality of second members 112, a protection layer 113, and the plate 114.

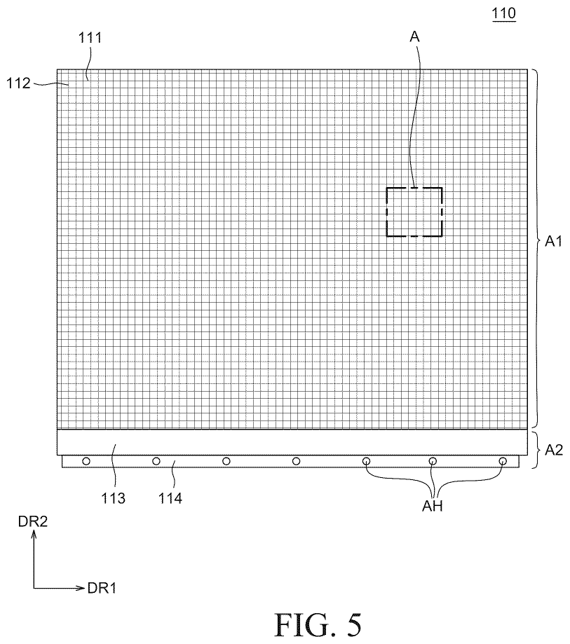

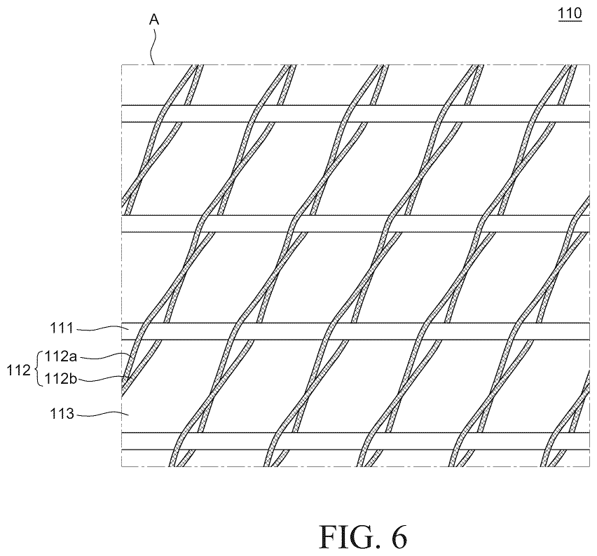

Hereinafter, the back cover 110 will be described in detail with reference to FIG. 5 and FIG. 6.

FIG. 5 is a plan view of a back cover of the flexible display device according to an example embodiment of the present disclosure. FIG. 6 is a perspective view of area A of FIG. 5.

As illustrated in FIG. 3 through FIG. 6, the back cover 110 may be disposed in the malleable area A1 and the rigid area A2.

The plate 114 of the back cover 110 may be disposed in the rigid area A2, and the plurality of first members 111 and the plurality of second members 112 may be disposed in the malleable area A1.

The plurality of first members 111 and the plurality of second members 112 may have a respective major axis in one direction. For example, each of the plurality of first members 111 and the plurality of second members 112 may have a wire shape but is not limited thereto.

The length of each of the plurality of first members 111 along a first direction DR1 may be equal to the width of the protection layer 113 along the first direction DR1. Also, the length of each of the plurality of first members 111 along the first direction DR1 may be equal to the width of the display panel 120 along the first direction DR1.

The plurality of first members 111 may have a major axis in a different direction from the plurality of second members 112. Thus, the plurality of first members 111 may intersect the plurality of second members 112. As shown in FIG. 5 and FIG. 6, the plurality of first members 111 and the plurality of second members 112 may form a mesh structure. Also, the plurality of first members 111 may intersect the plurality of second members 112. The plurality of first members 111 and the plurality of second members 112 may form a porous structure. Here, the structure of the plurality of first members 111 and the plurality of second members 112 shown in FIG. 5 and FIG. 6 is an example, and the present disclosure is not limited thereto. For example, the intervals and diameters of the plurality of first members 111 and the plurality of second members 112 may vary depending on the radius of curvature and rigidity requirements for the flexible display device 100.

Each of the plurality of first members 111 may be made of a material having a higher rigidity than each of the plurality of second members 112. For example, the plurality of first members 111 may be made of a metallic material, such as titanium, aluminum, and electrolytic galvanized iron (EGI). Alternatively, the plurality of first members 111 may be made of any one of plastic, carbon fiber, glass fiber, and polyvinyl chloride.

As illustrated in FIG. 4B, FIG. 5, and FIG. 6, the plurality of first members 111 may extend in a direction intersecting the bending, sliding, or rolling direction of the display part DP. For example, when the display part DP is bent, slid, or rolled in the second direction DR2, the plurality of first members 111 may extend in the first direction DR1. Thus, the plurality of first members 111 may serve to support the display panel 120 flat without being bent regardless of bending, sliding, or rolling of the display part DP.

As shown in FIG. 5 and FIG. 6, the plurality of second members 112 may be disposed extending in a direction intersecting the plurality of first members 111.

The plurality of second members 112 may be made of a different material from the plurality of first members 111. For example, the plurality of second members 112 may be made of a malleable material with a low rigidity, and each of the plurality of second members 112 may have a lower rigidity than each of the plurality of first members 111. For example, the plurality of second members 112 may be made of any one of nylon, polyurethane, silicone, and rubber. However, the material of the plurality of second members 112 is not limited thereto, and may be variously modified depending on the design as long as it can satisfy property conditions, such as the amount of deformation, radius of curvature, rigidity, etc.

As illustrated in FIG. 4A, FIG. 5, and FIG. 6, the plurality of second members 112 may extend in the bending, sliding, or rolling direction of the display part DP. For example, when the display part DP is bent, slid, or rolled in the second direction DR2, the plurality of second members 112 may extend in the second direction DR2. Thus, the plurality of second members 112 may be bent together with the display panel 120 along the bending, sliding, or rolling direction of the display part DP.

As shown in FIG. 6, each of the plurality of second members 112 may include a first sub-member 112a and a second sub-member 112b which intersect each other in a double helix form or are otherwise intertwined with each other. Further, the first sub-member 112a may intersect the second sub-member 112b with the plurality of first members 111 interposed therebetween.

In another aspect, the first sub-member 112a may be made of the same material as the second sub-member 112b. However, the present disclosure is not limited thereto.

As illustrated in FIG. 3, FIG. 4A, and FIG. 5, the plate 114 may be disposed in the rigid area A2. For example, the plate 114 may be disposed adjacent to at least one of both sides of the plurality of second members 112.

The plate 114 may be disposed in the rigid area A2 and may serve to support the display part DP. For example, the plate 114 may be coupled to a fastening member which rolls or slides the display part DP. For example, the flexible display device 100 may be a rollable display device. In this case, the plate 114 disposed at the lowermost region of the back cover 110 may be fastened to the roller (not shown) around which the display part DP may be wound.

Thus, as illustrated in FIG. 3 and FIG. 5, a plurality of fastening holes AH for fastening to the roller (not shown) may be provided at the lowermost region of the back cover 110. For example, a screw may be disposed to penetrate the roller (not shown) and the plurality of fastening holes AH and thus be fastened to the roller (not shown) and to the plate 114 of the back cover 110. Since the plate 114 is fastened to the roller (not shown), the back cover 110 may be wound around or unwound from the roller (not shown) depending on the direction of the rotation of the roller (not shown).

In another aspect, the number of fastening holes AH is shown in FIG. 5 by way of example, and the present disclosure is not limited thereto.

Although not shown in FIG. 5, another plate 114 may also be disposed at the uppermost region of the back cover 110. The plate 114 disposed at the uppermost region of the back cover 110 may be fixed to the head bar. Since the display part DP may be fixed to the head bar of the driver, the display part DP can be wound into the housing part HP and unwound out of the housing part HP depending on an operation of the driver.

The plate 114 may have a higher rigidity than the plurality of first members 111 and the plurality of second members 112. For example, the plate 114 may be made of a metal material, such as Steel Use Stainless (SUS) or Invar, or of plastic. However, the material of the plate 114 is not limited thereto, and may be variously modified depending on the design as long as it can satisfy property conditions, such as the amount of thermal deformation, radius of curvature, rigidity, etc.

The back cover 110 may include a protection layer 113. As shown in FIG. 4A and FIG. 4B, the protection layer 113 may be disposed in the malleable area A1 and may enclose the plurality of first members 111 and the plurality of second members 112.

As illustrated in FIG. 4B, an end of the protection layer 113 may be aligned with ends of the plurality of first members 111. Here, the protection layer 113 may be disposed in the rigid area A2. As shown in FIG. 4A, the protection layer 113 may extend from one ends of the plurality of second members 112 and cover a part of an upper surface and a part of a lower surface of the plate 114. Thus, the protection layer 113 may bond the plurality of first members 111 and the plurality of second members 112 to the plate 114.

The protection layer 113 may be made of, for example, resin. The protection layer 113 may enclose the plurality of first members 111 and the plurality of second members 112 and bond the plurality of first members 111 to the plurality of second members 112 by a hot press method.

Also, the protection layer 113 may fill the space between the plurality of first members 111 and the plurality of second members 112 and flatten upper and lower portions of the plurality of first members 111 and the plurality of second members 112. Thus, the protection layer 113 may secure the flatness of upper and lower portions of the back cover 110. Therefore, it is possible to suppress the appearance of the porous structure between the plurality of first members 111 and the plurality of second members 112.

To reduce a stress applied to a flexible display panel when the flexible display panel is bent, slid, or rolled, a plurality of openings is disposed in a back cover configured to support the flexible display panel. However, if the openings of the back cover are formed by an etching process, a complicated process such as a mask or photolithography process is performed. Therefore, processing time and cost may increase.

In another aspect, if the plurality of openings are formed in the back cover, the overall rigidity of the back cover may decrease. Therefore, the display panel may be deformed. For example, if a polarizing plate is disposed in the flexible display device, the polarizing plate may expand by absorbing moisture in a high humidity environment and may contract by discharging moisture in a low humidity environment. Therefore, the polarizing plate may be bent in a stretching direction. Accordingly, the polarizing plate and the flexible display panel to which the polarizing plate is attached can be bent.

Thus, in the flexible display device 100 according to an example embodiment of the present disclosure, the back cover 110 having a mesh structure composed of the plurality of first members 111 and the plurality of second members 112 may be disposed. Thus, a structure of the back cover 110 with openings can be implemented without performing an etching process. Therefore, it is possible to suppress a process variation which may occur during an etching process and also possible to reduce processing cost and procedure of the flexible display device 100. Also, in the flexible display device 100 according to an example embodiment of the present disclosure, the back cover 110 may be made of a fiber material. Therefore, it is possible to reduce manufacturing cost of the back cover 110 and thus possible to reduce manufacturing cost of the flexible display device 100.

Further, in the flexible display device 100 according to an example embodiment of the present disclosure, a high rigidity material may be disposed in a direction in which rigidity is needed or desired. Also, a flexible material which is stretchable may be disposed in a direction in which flexibility is needed or desired. Thus, the flexible display device 100 may have anisotropic properties. For example, the back cover 110 may have a mesh structure composed of the plurality of first members 111 and the plurality of second members 112 having a lower rigidity than the plurality of first members 111. Therefore, the plurality of first members 111 may support the display panel 120 by providing rigidity, and the plurality of second members 112 may provide flexibility and be bent in the bending, sliding, or rolling direction.

Further, the plurality of second members 112 may include a plurality of first sub-members 112a and a plurality of second sub-members 112b which intersect each other in a double helix form or are otherwise intertwined with each other. Thus, the plurality of first sub-members 112a and the plurality of second sub-members 112b may be transformed in the bending, sliding, or rolling direction. Therefore, in the flexible display device 100 according to an example embodiment of the present disclosure, it is possible to reduce a stress applied to the display panel 120 in the bending, sliding, or rolling direction. Also, it is possible to support the display panel 120 flat without being bent in a direction intersecting the bending, sliding, or rolling direction.

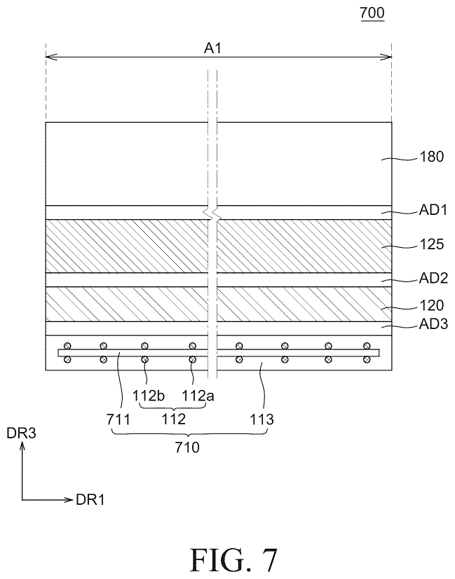

FIG. 7 is a schematic cross-sectional view of a flexible display device according to another example embodiment of the present disclosure. A flexible display device 700 shown in FIG. 7 is substantially the same as the flexible display device 100 shown in FIG. 1 through FIG. 6 except a plurality of first members 711 of aback cover 710. Therefore, redundant description may be omitted.

As shown in FIG. 7, the protection layer 113 may have the same width as the back cover 710 along the first direction DR1. Also, the length of the plurality of first members 711 along the first direction DR1 may be smaller than the width of the protection layer 113 along the first direction DR1. Thus, the protection layer 113 may cover ends of the plurality of first members 711 extending in the first direction DR1. Further, the plurality of first members 711 may be disposed within a width defined by ends of the polarizing plate 125 extending in the first direction DR1, ends of the cover window 180 extending in the first direction DR1, and ends of the display panel 120 extending in the first direction DR1. In other words, the polarizing plate 125, the cover window 180, and the display panel 120 may extend farther in the first direction DR1 than the plurality of first members 711. Furthermore, the plurality of first members 711 may be protected by the display panel 120, the cover window 180, and the protection layer 113.

Thus, in the flexible display device 700 according to another example embodiment of the present disclosure, the back cover 710 having a mesh structure composed of the plurality of first members 711 and the plurality of second members 112 may be disposed. Therefore, it is possible to reduce manufacturing cost of the back cover 710 and thus possible to reduce manufacturing cost of the flexible display device 700.

Further, in the flexible display device 700 according to another example embodiment of the present disclosure, a high rigidity material may be disposed in a direction in which rigidity is needed or desired. Also, a flexible material which is stretchable may be disposed in a direction in which flexibility is needed or desired. Thus, the flexible display device 700 may have anisotropic properties. Therefore, it is possible to reduce a stress applied to the display panel 120 in the bending, sliding, or rolling direction. Also, it is possible to support the display panel 120 flat without being bent in a direction intersecting the bending, sliding, or rolling direction.

In another aspect, to enhance malleability of a back cover, a plurality of first members may be formed to have a relatively small thickness and may have a wire shape extending in one direction. Thus, ends of the plurality of first members may be pointed. Therefore, if the respective ends of the plurality of first members are exposed from a protection layer of the back cover, the ends of the plurality of first members may be damaged. Also, the user may be hurt by the pointed ends of the plurality of first members. Further, if the ends of the plurality of first members are exposed from the protection layer, a gap may be formed between the protection layer and the first members by external impacts. Therefore, the adhesive strength between the protection layer and the plurality of first members may decrease, and the back cover may be deformed. Therefore, the overall rigidity and the reliability of the back cover may be degraded.

Thus, in the flexible display device 700 according to another example embodiment of the present disclosure, the plurality of first members 711 of the back cover 710 may be disposed within the protection layer 113. In other words, the protection layer 113 may extend farther in the first direction DR1 than the plurality of first members 711. Thus, the protection layer 113 may cover the ends of the plurality of first members 711. Therefore, it is possible to suppress the exposure of the ends of the plurality of first members 711 to the outside. Also, it is possible to eliminate or reduce a risk of the user being hurt by the ends of the plurality of first members 711. Further, it is possible to suppress the deformation of the back cover 710 caused by the ends of the plurality of first members 711 being exposed. Accordingly, the reliability of the back cover 710 can be improved.

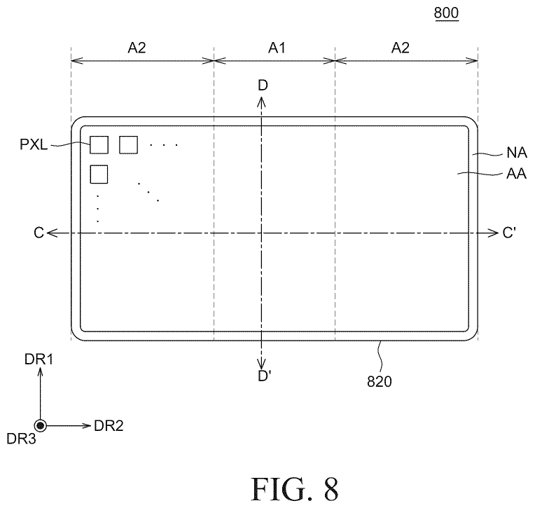

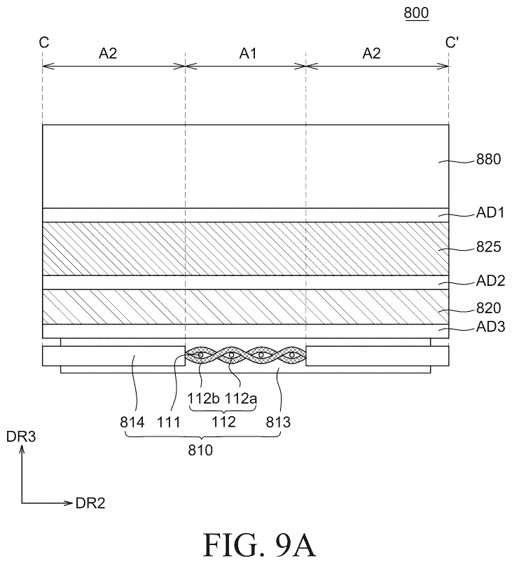

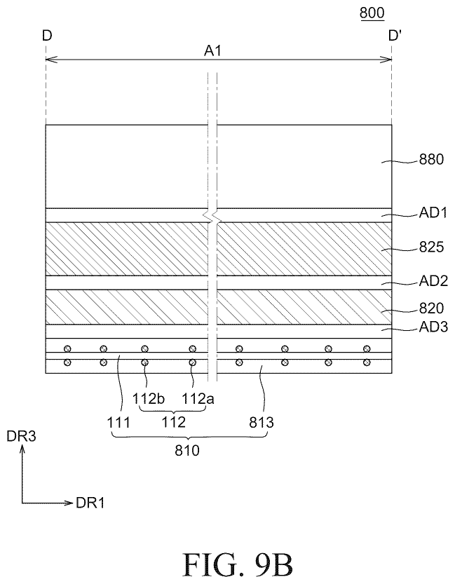

FIG. 8 is a schematic plan view of a flexible display device according to yet another example embodiment of the present disclosure. Specifically, FIG. 8 is a plan view of an example foldable display device. FIG. 9A and FIG. 9B are schematic cross-sectional views of the flexible display device according to yet another example embodiment of the present disclosure. FIG. 9A is a cross-sectional view taken along the line C-C′ of FIG. 8. FIG. 9B is a cross-sectional view taken along the line D-D′ of FIG. 8.

FIG. 8 illustrates only a display panel 820 for the convenience of description. A flexible display device 800 shown in FIG. 8 is substantially the same as the flexible display device 100 shown in FIG. 1 through FIG. 6, except a display panel 820, a polarizing plate 825, a cover window 880, a plate 814 of a back cover 810, and the exclusion of the housing part HP. Therefore, redundant description may be omitted.

The flexible display device 800 may include the malleable area A1 and the rigid areas A2. The rigid areas A2 and the malleable area A1 may be disposed along a folding direction of the flexible display device 800.

The malleable area A1 is an area where the display panel 820 may be folded. For example, the malleable area A1 may be folded with a specific radius of curvature around a folding axis. For example, the folding axis may be in the first direction DR1. Thus, in the malleable area A1, the display panel 820 may be folded in the second direction DR2 along the folding axis extending the first direction DR1. Therefore, the malleable area A1 here may be referred to as a folding area.

The rigid areas A2 of the flexible display device 800 may be adjacent to the malleable area A1. The rigid areas A2 may be areas which are not folded when the display panel 820 is folded. That is, the rigid areas A2 may be maintained flat when the display panel 820 is folded. Therefore, the rigid areas A2 may be referred to as non-folding areas.

The rigid areas A2 may be disposed at respective sides of the malleable area A1. That is, the rigid areas A2 may be disposed along the second direction DR2 with the malleable area A1 interposed therebetween. Therefore, when the flexible display device 800 is folded around the folding axis, the rigid areas A2 may face or overlap each other.

As shown in FIG. 9A and FIG. 9B, all of the back cover 810, the display panel 820, the polarizing plate 825, the cover window 880, the first adhesive layer AD1, the second adhesive layer AD2, and the third adhesive layer AD3 of the flexible display device 800 may be disposed in the malleable area A1 and the rigid areas A2.

Thus, a part of the polarizing plate 825, a part of the cover window 880, a part of the first adhesive layer AD1, a part of the second adhesive layer AD2, and a part of the third adhesive layer AD3 may be disposed in the malleable area A1. Further, other parts of the polarizing plate 825, other parts of the cover window 880, other parts of the first adhesive layer AD1, other parts of the second adhesive layer AD2, and other parts of the third adhesive layer AD3 may be disposed in the rigid areas A2, respectively.

A part of the display panel 820 may overlap the malleable area A1, and other parts of the display panel 820 may respectively overlap the rigid areas A2. Thus, the display panel 820 of the flexible display device 800 may be implemented as a flexible display panel to be folded.

As illustrated in FIG. 8, the display panel 820 of the flexible display device 800 may include a display area AA, in which a plurality of pixels PXL is disposed, and a non-display area NA enclosing the display area AA. Thus, a part of the display area AA of the display panel 820 and a part of the non-display area NA may be disposed in the malleable area A1.

FIG. 8 illustrates that a part of the display area AA and a part of the non-display area NA are disposed in the malleable area A1. However, the present disclosure is not limited thereto. The non-display area NA may not be disposed in the malleable area A1, but only a part of the display area AA may be disposed in the malleable area A1.

A part of the back cover 810 may overlap the malleable area A1, and other parts of the back cover 810 may respectively overlap the rigid areas A2.

The back cover 810 may be folded together with the display panel 820 in the malleable area A1. For example, the back cover 810 may be folded in the second direction DR2, and the display panel 820 may be folded together with the back cover 810 in the second direction DR2.

The back cover 810 may contain a malleable material to suppress deformation even when the display panel 820 is repeatedly folded and unfolded. For example, the back cover 810 may include the plurality of first members 111 and the plurality of second members 112 disposed in the malleable area A1, and the plates 814 disposed in the rigid areas A2. Thus, the back cover 810 may include the folding area where the plurality of first members 111 and the plurality of second members 112 are disposed and the non-folding areas where the plates 814 are disposed.

The plurality of second members 112 may extend in the folding direction of the flexible display device 800. For example, as illustrated in FIG. 9A and FIG. 9B, if the flexible display device 800 is folded in the second direction DR2, the plurality of second members 112 may extend in the second direction DR2. Thus, the plurality of second members 112 may be bent or folded together with the display panel 820 along the folding direction of the flexible display device 800.

In another aspect, as shown in FIG. 9A, if the rigid areas A2 are disposed at respective sides of the malleable area A1 in the second direction DR2, the plates 814 may be disposed at respective ends of the plurality of second members 112 and be connected to the plurality of second members 112.

Thus, in the flexible display device 800 according to yet another example embodiment of the present disclosure, the back cover 810 having a mesh structure composed of the plurality of first members 111 and the plurality of second members 112 may be disposed. Therefore, it is possible to reduce manufacturing cost of the back cover 810 and thus possible to reduce manufacturing cost of the flexible display device 800.

Also, in the flexible display device 800 according to yet another example embodiment of the present disclosure, the back cover 810 may include the plurality of first members 111 and the plurality of second members 112 having a lower rigidity than the plurality of first members 111. Further, the plurality of second members 112 may include the plurality of first sub-members 112a and the plurality of second sub-members 112b which intersect each other in a double helix form or are otherwise intertwined with each other.

Furthermore, in the flexible display device 800 according to yet another example embodiment of the present disclosure, a high rigidity material may be disposed in a direction in which rigidity is needed or desired. Also, a flexible material which is stretchable may be disposed in a direction in which flexibility is needed or desired. Thus, the flexible display device 800 may have anisotropic properties. Therefore, it is possible to reduce a stress applied to the display panel 820 in the folding direction. Also, it is possible to support the display panel 820 flat without being bent in a direction intersecting the folding direction.

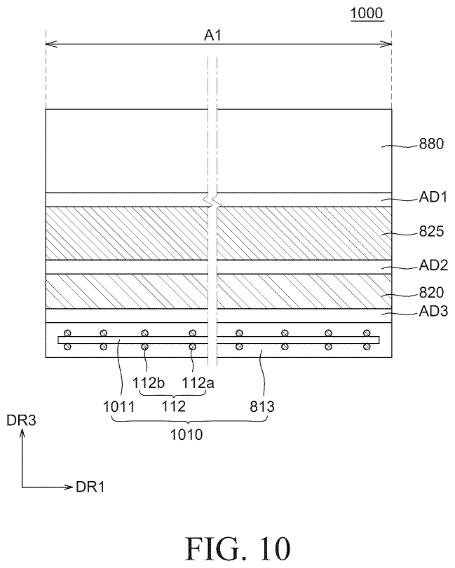

FIG. 10 is a schematic cross-sectional view of a flexible display device according to still another example embodiment of the present disclosure. A flexible display device 1000 shown in FIG. 10 is substantially the same as the flexible display device 800 shown in FIG. 8 through FIG. 9B, except a plurality of first members 1011 of a back cover 1010. Therefore, redundant description may be omitted.

As shown in FIG. 10, a protection layer 813 may have the same width as the back cover 1010 along the first direction DR1. Also, the length of the plurality of first members 1011 along the first direction DR1 may be smaller than the width of the protection layer 813 along the first direction DR1. Thus, the protection layer 813 may cover ends of the plurality of first members 1011 extending in the first direction DR1. Further, the plurality of first members 1011 may be disposed within a width defined by ends of the polarizing plate 825 extending in the first direction DR1, ends of the cover window 880 extending in the first direction DR1, and ends of the display panel 820 extending in the first direction DR1. In other words, the polarizing plate 825, the cover window 880, and the display panel 820 may extend farther in the first direction DR1 than the plurality of first members 1011. Furthermore, the plurality of first members 1011 may be protected by the display panel 820, the cover window 880, and the protection layer 813.

Thus, in the flexible display device 1000 according to still another example embodiment of the present disclosure, the back cover 1010 having a mesh structure composed of the plurality of first members 1011 and the plurality of second members 112 may be disposed. Therefore, it is possible to reduce manufacturing cost of the back cover 1010 and thus possible to reduce manufacturing cost of the flexible display device 1000.

Further, in the flexible display device 1000 according to still another example embodiment of the present disclosure, a high rigidity material may be disposed in a direction in which rigidity is needed or desired. Also, a flexible material which is stretchable may be disposed in a direction in which flexibility is needed or desired. Thus, the flexible display device 1000 may have anisotropic properties. Therefore, it is possible to reduce a stress applied to the display panel 820 in a folding direction. Also, it is possible to support the display panel 820 flat without being bent in a direction intersecting the folding direction.

In the flexible display device 1000 according to still another example embodiment of the present disclosure, the plurality of first members 1011 of the back cover 1010 may be disposed within the protection layer 813. In other words, the protection layer 813 may extend farther in the first direction DR1 than the plurality of first members 1011. Thus, the protection layer 813 may cover ends of the plurality of first members 1011. Therefore, it is possible to suppress the exposure of the ends of the plurality of first members 1011 to the outside. Also, it is possible to eliminate or reduce a risk of the user being hurt by exposed ends of the plurality of first members 1011. Further, it is possible to suppress the deformation of the back cover 1010 caused by the ends of the plurality of first members 1011 being exposed. Accordingly, the reliability of the back cover 1010 can be improved.

Example embodiments of the present disclosure can also be described as follows:

According to an aspect of the present disclosure, a flexible display device may include: a flexible display panel; and a back cover at a rear surface of the flexible display panel and supporting the flexible display panel. The back cover may include: a plurality of first members extending in a first direction; and a plurality of second members extending in a second direction and intersecting the plurality of first members, the plurality of second members including a different material from the plurality of first members.

In some example embodiments, the plurality of first members and the plurality of second members may have a wire shape and may intersect one another in a mesh pattern.

In some example embodiments, the plurality of second members may have a lower rigidity than the plurality of first members, and the flexible display panel and the back cover may be configured to be bendable, foldable, slidable, or rollable together in the second direction.

In some example embodiments, at least one of the plurality of second members may include a first sub-member and a second sub-member intertwined with each other, and the first sub-member may intersect the second sub-member with the plurality of first members interposed therebetween.

In some example embodiments, the plurality of first members may be made of one or more of metal, plastic, carbon fiber, glass fiber, and polyvinyl chloride. The plurality of second members may be made of one or more of nylon, polyurethane, silicone, and rubber.

In some example embodiments, the back cover may further include a protection layer enclosing the plurality of first members and the plurality of second members.

In some example embodiments, the protection layer may fill a space between the plurality of first members and the plurality of second members.

In some example embodiments, a length of the plurality of first members in the first direction may be smaller than a width of the flexible display panel in the first direction and may be smaller than a width of the protection layer in the first direction. The protection layer may cover ends of the plurality of first members.

In some example embodiments, the back cover may further include at least one plate disposed adjacent to a respective end of the plurality of second members in the second direction. The at least one plate may have a higher rigidity than the plurality of first members and the plurality of second members.

In some example embodiments, the back cover may further include a protection layer covering a part of an upper surface and a part of a lower surface of the at least one plate, the protection layer enclosing the plurality of first members and the plurality of second members.

In some example embodiments, the at least one plate may include a first plate connected to one end of the plurality of second members and a second plate connected to an opposite end of the plurality of second members.

In some example embodiments, the flexible display device may have a malleable area and at least one rigid area adjacent to the malleable area in the second direction. The flexible display panel and the back cover may be disposed in the malleable area and may be configured to be bent, folded, slid, or rolled in the malleable area.

In some example embodiments, the plurality of first members and the plurality of second members may be disposed entirely in the malleable area.

In some example embodiments, the flexible display panel may be disposed entirely in the malleable area.

In some example embodiments, the back cover may further include at least one plate disposed respectively in the at least one rigid area and having a higher rigidity than the plurality of second members. The at least one plate may be connected to the plurality of second members disposed in the malleable area.

In some example embodiments, the flexible display panel may be further disposed in the at least one rigid area and may overlap the at least one plate.

In some example embodiments, the flexible display device may further include a housing configured to accommodate the flexible display panel and the back cover.

According to another aspect of the present disclosure, a display device, having a malleable area and at least one rigid area adjacent to the malleable area, may include: a flexible display panel in the malleable area; and a back cover at a rear surface of the flexible display panel and supporting the flexible display panel. The back cover may include: a plurality of first members in the malleable area and extending in a first direction; and a plurality of second members in the malleable area and intersecting the plurality of first members in a mesh pattern, the plurality of second members including a different material from the plurality of first members.

In some example embodiments, the plurality of second members may have a lower rigidity than the plurality of first members. The plurality of second members may extend in a second direction intersecting the first direction. The flexible display panel and the back cover may be configured to be bendable, foldable, slidable, or rollable together in the second direction.

In some example embodiments, the plurality of first members and the plurality of second members may have a wire shape. At least one of the plurality of second members may include a first sub-member and a second sub-member intertwined with each other. The first sub-member may intersect the second sub-member with the plurality of first members interposed therebetween.

In some example embodiments, the back cover may further include a protection layer enclosing the plurality of first members and the plurality of second members.

In some example embodiments, the protection layer may fill a space between the plurality of first members and the plurality of second members.

In some example embodiments, a length of the plurality of first members in the first direction may be smaller than a width of the flexible display panel in the first direction, and the protection layer may cover both ends of the plurality of first members.

In some example embodiments, the back cover may further include at least one plate respectively in the at least one rigid area and connected to the plurality of second members. The at least one plate may have a higher rigidity than the plurality of second members.

In some example embodiments, the back cover may further include a protection layer covering a part of an upper surface and a part of a lower surface of the at least one plate, the protection layer enclosing the plurality of first members and the plurality of second members.

In some example embodiments, the at least one plate may include a first plate connected to one end of the plurality of second members and a second plate connected to an opposite end of the plurality of second members.

In some example embodiments, the plurality of second members may extend in a second direction intersecting the first direction. The flexible display panel and the back cover may be configured to be foldable together in the second direction. With the back cover in a folded state, the first plate may overlap the second plate.

In some example embodiments, the display device may further include a housing configured to accommodate the flexible display panel and the back cover.

It will be apparent to those skilled in the art that the present disclosure is not limited by the above-described example embodiments and the accompanying drawings, and that various substitutions, modifications, and variations can be made in the present disclosure without departing from the spirit or scope of the disclosures. Therefore, the above example embodiments of the present disclosure are provided for illustrative purposes and are not intended to limit the scope or technical concept of the present disclosure. The protective scope of the present disclosure should be construed based on the following claims and their equivalents, and it is intended that the present disclosure cover all modifications and variations of this disclosure that come within the scope of the claims and their equivalents.

What is claimed is:

1. A flexible display device, comprising:
a flexible display panel; and
a back cover at a rear surface of the flexible display panel and supporting the flexible display panel, the back cover including:
a plurality of first members extending in a first direction; and
a plurality of second members extending in a second direction and intersecting the plurality of first members, the plurality of second members including a different material from the plurality of first members.

2. The flexible display device of claim 1, wherein:
the plurality of first members and the plurality of second members have a wire shape and intersect one another in a mesh pattern.

3. The flexible display device of claim 1, wherein:
the plurality of second members have a lower rigidity than the plurality of first members; and
the flexible display panel and the back cover are configured to be bendable, foldable, slidable, or rollable together in the second direction.

4. The flexible display device of claim 1, wherein:
at least one of the plurality of second members includes a first sub-member and a second sub-member intertwined with each other; and
the first sub-member intersects the second sub-member with the plurality of first members interposed therebetween.

5. The flexible display device of claim 1, wherein:
the plurality of first members are made of one or more of metal, plastic, carbon fiber, glass fiber, and polyvinyl chloride; and
the plurality of second members are made of one or more of nylon, polyurethane, silicone, and rubber.

6. The flexible display device of claim 1, wherein the back cover further includes a protection layer enclosing the plurality of first members and the plurality of second members.

7. The flexible display device of claim 6, wherein the protection layer fills a space between the plurality of first members and the plurality of second members.

8. The flexible display device of claim 6, wherein:
a length of the plurality of first members in the first direction is smaller than a width of the flexible display panel in the first direction and is smaller than a width of the protection layer in the first direction; and
the protection layer covers ends of the plurality of first members.

9. The flexible display device of claim 1, wherein:
the back cover further includes at least one plate disposed adjacent to a respective end of the plurality of second members in the second direction; and
the at least one plate has a higher rigidity than the plurality of first members and the plurality of second members.

10. The flexible display device of claim 9, wherein the back cover further includes a protection layer covering a part of an upper surface and a part of a lower surface of the at least one plate, the protection layer enclosing the plurality of first members and the plurality of second members.

11. The flexible display device of claim 9, wherein the at least one plate includes a first plate connected to one end of the plurality of second members and a second plate connected to an opposite end of the plurality of second members.

12. The flexible display device of claim 1, wherein:
the flexible display device has a malleable area and at least one rigid area adjacent to the malleable area in the second direction; and
the flexible display panel and the back cover are disposed in the malleable area and are configured to be bent, folded, slid, or rolled in the malleable area.

13. The flexible display device of claim 12, wherein the plurality of first members and the plurality of second members are disposed entirely in the malleable area.

14. The flexible display device of claim 12, wherein the flexible display panel is disposed entirely in the malleable area.

15. The flexible display device of claim 12, wherein:
the back cover further includes at least one plate disposed respectively in the at least one rigid area and having a higher rigidity than the plurality of second members; and
the at least one plate is connected to the plurality of second members disposed in the malleable area.

16. The flexible display device of claim 15, wherein the flexible display panel is further disposed in the at least one rigid area and overlaps the at least one plate.

17. The flexible display device of claim 1, further comprising a housing configured to accommodate the flexible display panel and the back cover.

18. A display device having a malleable area and at least one rigid area adjacent to the malleable area, the display device comprising:
a flexible display panel in the malleable area; and
a back cover at a rear surface of the flexible display panel and supporting the flexible display panel, the back cover including:
a plurality of first members in the malleable area and extending in a first direction; and
a plurality of second members in the malleable area and intersecting the plurality of first members in a mesh pattern, the plurality of second members including a different material from the plurality of first members.

19. The display device of claim 18, wherein:
the plurality of second members have a lower rigidity than the plurality of first members;
the plurality of second members extend in a second direction intersecting the first direction; and
the flexible display panel and the back cover are configured to be bendable, foldable, slidable, or rollable together in the second direction.

20. The display device of claim 18, wherein:
the plurality of first members and the plurality of second members have a wire shape;
at least one of the plurality of second members includes a first sub-member and a second sub-member intertwined with each other; and
the first sub-member intersects the second sub-member with the plurality of first members interposed therebetween.

21. The display device of claim 18, wherein the back cover further includes a protection layer enclosing the plurality of first members and the plurality of second members.

22. The display device of claim 21, wherein the protection layer fills a space between the plurality of first members and the plurality of second members.

23. The display device of claim 21, wherein:
a length of the plurality of first members in the first direction is smaller than a width of the flexible display panel in the first direction; and
the protection layer covers both ends of the plurality of first members.

24. The flexible display device of claim 18, wherein:
the back cover further includes at least one plate respectively in the at least one rigid area and connected to the plurality of second members; and
the at least one plate has a higher rigidity than the plurality of second members.

25. The flexible display device of claim 24, wherein the back cover further includes a protection layer covering a part of an upper surface and a part of a lower surface of the at least one plate, the protection layer enclosing the plurality of first members and the plurality of second members.

26. The flexible display device of claim 24, wherein the at least one plate includes a first plate connected to one end of the plurality of second members and a second plate connected to an opposite end of the plurality of second members.

27. The flexible display of claim 26, wherein:
the plurality of second members extend in a second direction intersecting the first direction;
the flexible display panel and the back cover are configured to be foldable together in the second direction; and
with the back cover in a folded state, the first plate overlaps the second plate.

28. The display device of claim 18, further comprising a housing configured to accommodate the flexible display panel and the back cover.
